(19) United States
(12) Patent Application Publication
(10) Pub. No.: US 2021/0048547 A1
(43) Pub. Date: Feb. 18, 2021

(54) METHOD FOR DETERMINING THE CHARACTERISTIC PARAMETERS OF STIMULATION INTERVALS OF MULTI-STAGE FRACTURED HORIZONTAL WELL IN UNCONVENTIONAL OIL AND GAS RESERVOIR

(71) Applicant: SOUTHWEST PETROLEUM UNIVERSITY, Chengdu (CN)

(72) Inventors: Renshi NIE, Chengdu (CN); Xiaohui FAN, Chengdu (CN); Min LI, Chengdu (CN); Jie ZHOU, Chengdu (CN); Xianzong ZHOU, Chengdu (CN); Shuai ZHANG, Chengdu (CN); Tianqi CHEN, Chengdu (CN)

(73) Assignee: SOUTHWEST PETROLEUM UNIVERSITY, Chengdu (CN)

(21) Appl. No.: 16/745,286

(22) Filed: Jan. 16, 2020

(30) Foreign Application Priority Data
Aug. 12, 2019 (CN) 201910737729.X

(51) Int. Cl. G01V 1/50; G01V 1/30; E21B 47/06; G06F 7/24

(52) U.S. Cl. CPC G01V 1/50; G01V 1/306; G01V 2210/6248; G06F 7/24; E21B 47/06

(57) ABSTRACT

The present invention discloses a method for determining the characteristic parameters of stimulation intervals of multi-stage fractured horizontal well in unconventional oil and gas reservoir, comprising the following steps:

Step 1: Collect and sort out basic information and data of the well and reservoir;

Step 2: Collect and sort out daily test pressure data of the well;

Step 3: Collect and sort out daily test production data of the well;

Step 4: Split production data to obtain the production data of fracturing stimulation intervals at all stages;

Step 5: Select popular advanced production decline analysis software for oil and gas wells, input the basic information and data of the well and reservoir, the daily test pressure data and the production data of fracturing stimulation intervals at all stages obtained by splitting, and draw the double logarithmic curve of dimensionless production integral and dimensionless production integral derivative with time respectively;

Step 6: Fit and interpret the stimulation intervals at all stages to obtain the characteristic parameters of each stimulation interval. The method disclosed in the present invention can evaluate the reservoir characteristic parameters and fracture characteristic parameters of the stimulation intervals at all stages in an economical and efficient manner, and has important guiding significance for the efficient development of multi-stage fractured horizontal well after fracturing.

### CROSS-REFERENCE TO TELATED APPLICATION

This application claims priority to Chinese Patent Application No. 201910737729.X, filed on Aug. 12, 2019, the contents of which are incorporated herein by reference in their entirety.

### TECHNICAL FIELD

The present invention relates to the prior art of unconventional oil and gas development, in particular to a method for determining the characteristic parameters of stimulation intervals of multi-stage fractured horizontal well in unconventional oil and gas reservoir.

### BACKGROUND

With the rapid development of industrialization, the relationship between supply and demand of oil resources in China is becoming increasingly tense, and the exploitation of oil and gas reservoir is constantly deepened, unconventional oil and gas reservoir plays an increasingly important role in energy supply. Due to the characteristics of low permeability, ultra-low permeability, and tightness of unconventional oil and gas reservoir, with conventional horizontal well development methods, there are many challenges such as low production and low effective utilization of reserves, making it difficult to meet the requirements for efficient development. In recent years, with the continuous improvement of fracturing technology, multi-stage fractured horizontal well technology has begun to be used in the development of unconventional oil and gas reservoir. Multi-stage fracturing of the reservoir will make multiple fractures, enhance the production of single well, expand the drainage area, and improve effective utilization degree of reserves, so as to achieve efficient development.

With high heterogeneity of unconventional oil and gas reservoir, great difference in physical properties of stimulation intervals at all stages of long horizontal well, the size and characteristics of artificial fractures in different interval are different after fracturing. It is the basis of high-efficiency development after fracturing to make clear the fracture characteristic parameters (such as fracture half-length and conductivity) and reservoir characteristic parameters of stimulation intervals at all stages.

At present, the fracture and reservoir characteristic parameters of multi-stage fractured horizontal well are interpreted mainly by micro-seismic monitoring technology.

With micro-seismic monitoring technology, the seismic waves generated when fractures are formed by multiple-stage fracturing can be detected by a geophone, the distance to the source is calculated based on the time difference between the monitored compression and shear waves, and the underground fractures are imaged and analyzed according to the temporal and spatial distribution at the rock fracture location to discover the fracture distribution pattern and obtain the fracture characteristic parameters. The main challenges encountered in micro-seismic monitoring many problems are insufficient vertical positioning resolution of surface monitoring, low horizontal positioning resolution of underground monitoring, high operation cost, limited parameters interpretation, and failure to interpret fracture conductivity.

Therefore, with respect to the development of multi-stage fractured horizontal wells, there are still great technical challenges to evaluate the reservoir characteristic parameters and fracture characteristic parameters of the stimulation intervals at all stages in an economical and efficient manner.

### SUMMARY

In view of the above challenges, the present invention provides a method for determining characteristic parameters of each stimulation interval of multi-stage fractured horizontal well in unconventional oil and gas reservoir to evaluate the reservoir characteristic parameters and fracture characteristic parameters of the stimulation intervals at all stages in an economical and efficient manner.

The technical solution of the present invention is described as follows:

A method for determining the characteristic parameters of stimulation intervals of multi-stage fractured horizontal well in unconventional oil and gas reservoir, comprising the following steps:

Step 1: Collect and sort out basic information and data of the multi-stage fractured horizontal well in unconventional oil and gas reservoir; the basic information and data of the well and the reservoir include fluid viscosity, compression coefficient, volume coefficient, deviation factor, original oil saturation or original gas saturation, length of stimulation interval, porosity of stimulation interval, and oil saturation or gas saturation of stimulation interval.

Step 2: Collect daily test pressure data of the multi-stage fractured horizontal well in unconventional oil and gas reservoir, screen and sort out the data according to the quality of the pressure data, and exclude the values with deviations greater than 20% from both left and right adjacent values.

Step 3: Collect daily test production data of the multi-stage fractured horizontal well in unconventional oil and gas reservoir, screen and sort out the data according to the quality of the production data, and exclude the values with deviations greater than 20% from both left and right adjacent values.

Step 4: Split the production data sorted out in Step 3 to obtain the production data of fracturing stimulation intervals at all stages, specifically as follows:

Step 41: According to the logging data collected in Step 1, record the length, porosity, oil saturation, or gas saturation of each fracturing stimulation interval;

Step 42: Determine the weight coefficient Wᵢ of each fracturing stimulation interval in the production splitting, specifically as follows:

$$\begin{matrix}{W}_{o i} = \frac{{L}_{i} {φ}_{i} {S}_{oi}}{{\sum }_{i = 1}^{N} ( {L}_{i} {φ}_{i} {S}_{oi} )} , ( i = 1 , 2 , … N ) & ( 1 ) \\ {W}_{g i} = \frac{{L}_{i} {φ}_{i} {S}_{gi}}{{\sum }_{i = 1}^{N} ( {L}_{i} {φ}_{i} {S}_{gi} )} , ( i = 1 , 2 , … N ) & ( 2 )\end{matrix}$$

### Where,

Wₒᵢ refers to the weight coefficient of Fracturing Stimulation Interval i of the oil reservoir in the production splitting, which is dimensionless;

W_{gi} refers to the weight coefficient of Fracturing Stimulation Interval i of the gas reservoir in the production splitting, which is dimensionless;

Lᵢ refers to the length of Fracturing Stimulation Interval i, in m;

φᵢ refers to the porosity of Fracturing Stimulation Interval i, which is dimensionless;

Sₒᵢ refers to the oil saturation of Fracturing Stimulation Interval i, which is dimensionless;

S_{gi} refers to the gas saturation of Fracturing Stimulation Interval i, which is dimensionless;

Step 43: Calculate the production after splitting of each fracturing stimulation interval according to the weight coefficient Wᵢ of each fracturing stimulation interval determined in Step 42, specifically as follows:

qᵢ=Wᵢq, (i=1,2, . . . N) (3)

### Where,

Lᵢ refers to the production of Fracturing Stimulation Interval i, in 10,000 m³;

Wᵢ refers to the weight coefficient of Fracturing Stimulation Interval i in the production splitting, which is dimensionless;

q refers to the daily production of the horizontal well, in 10,000 m³.

Step 5: Select a popular advanced production decline analysis software for oil and gas wells, input the logging data and the basic parameters of the reservoir described in Step 1, the pressure data described in Step 2, and the production data and corresponding time described in Step 4, and draw the double logarithmic curve of dimensionless production integral and dimensionless production integral derivative with time respectively.

Step 6: Select a production decline fitting model for multi-stage fractured horizontal wells, conduct fitting and interpretation for each fracturing stimulation interval according to the double logarithmic curve described in Step 5 and the ordinal number of each fracturing stimulation interval, and obtain the fracture characteristic parameters and reservoir characteristic parameters of each fracturing stimulation interval. The fracture characteristic parameters include the conductivity and half-length of fracture, and the reservoir characteristic parameters include the horizontal permeability, vertical permeability and skin of the reservoir.

The advantages of the present invention are to accurately obtain the fracture characteristic parameters and reservoir characteristic parameters of each fracturing stimulation interval according to the daily protection test data of multi-stage fractured horizontal well to provide data support for future efficient exploitation of the reservoir. Compared with micro-seismic monitoring methods, the present invention not only solves the problem of high test cost, but also obtains fracture conductivity, formation permeability, and other characteristic parameters. The method for evaluating the fracture characteristic parameters of fracturing stimulation intervals at all stages and the reservoir characteristic parameters disclosed in the present invention is featured by low cost, short time consumption, and accurate interpretation results, and it suitable for various tight unconventional oil and gas reservoirs with low permeability and ultra-low-permeability.

### BRIEF DESCRIPTION OF THE DRAWINGS

In order to explain the embodiments of the present invention or the technical solutions in the prior art more clearly, the following will make a brief introduction to the drawings needed in the description of the embodiments or the prior art. Obviously, the drawings in the following description are merely some embodiments of the present invention. For those of ordinary skill in the art, other drawings can be obtained based on these drawings without any creative effort.

FIG. 1 is a schematic view of X-Y plane structure of the multi-stage fractured horizontal well;

FIG. 2 is a schematic view of X-Z plane structure of the multi-stage fractured horizontal well;

FIG. 3 is a schematic view of X-Y plane structure of the multi-stage fractured horizontal well of a preferred embodiment of the present invention;

FIG. 4 is a view of daily test pressure and production data of a preferred embodiment of the present invention;

FIG. 5 is a view of double logarithmic curve of dimensionless production integral and dimensionless production integral derivative of fracture stimulation interval at the first stage of a preferred embodiment of the present invention;

FIG. 6 is a view of double logarithmic curve of dimensionless production integral and dimensionless production integral derivative of fracture stimulation interval at the second stage of a preferred embodiment of the present invention;

FIG. 7 is a view of double logarithmic curve of dimensionless production integral and dimensionless production integral derivative of fracture stimulation interval at the third stage of a preferred embodiment of the present invention;

FIG. 8 is a view of double logarithmic curve of dimensionless production integral and dimensionless production integral derivative of fracture stimulation interval at the fourth stage of a preferred embodiment of the present invention;

FIG. 9 is a view of double logarithmic curve of dimensionless production integral and dimensionless production integral derivative of fracture stimulation interval at the fifth stage of a preferred embodiment of the present invention;

FIG. 10 is a view of double logarithmic curve of dimensionless production integral and dimensionless production integral derivative of fracture stimulation interval at the sixth stage of a preferred embodiment of the present invention;

FIG. 11 is a view of double logarithmic curve of dimensionless production integral and dimensionless production integral derivative of fracture stimulation interval at the seventh stage of a preferred embodiment of the present invention.

### DETAILED DESCRIPTION

The present invention is further described with reference to the drawings and embodiments.

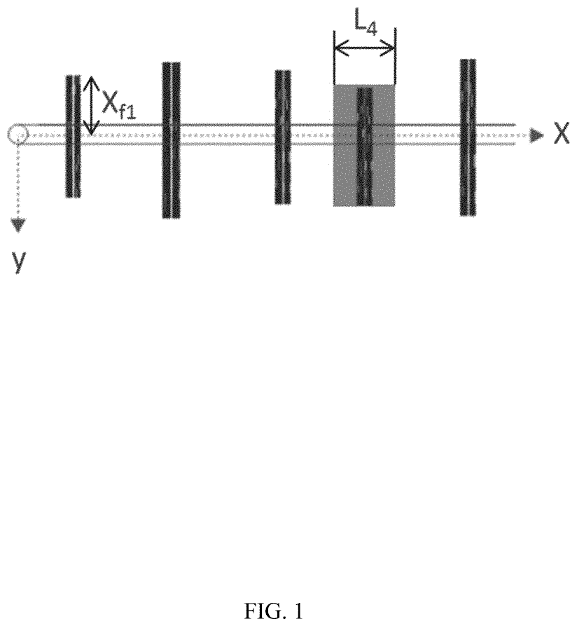

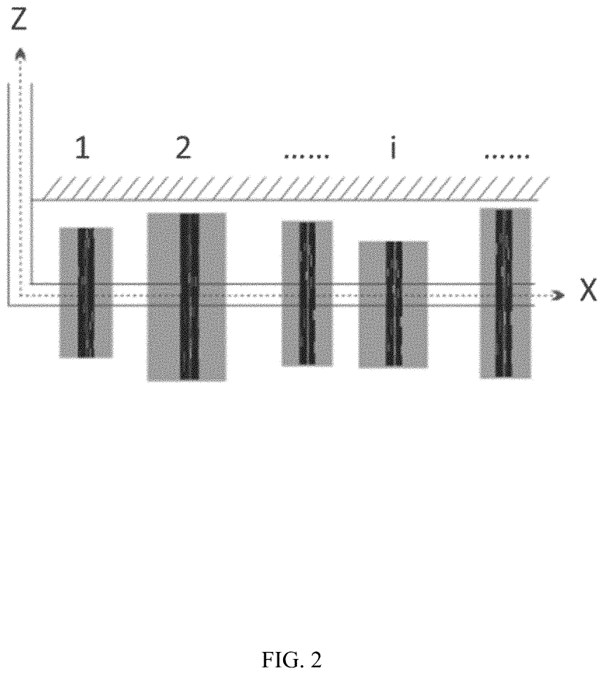

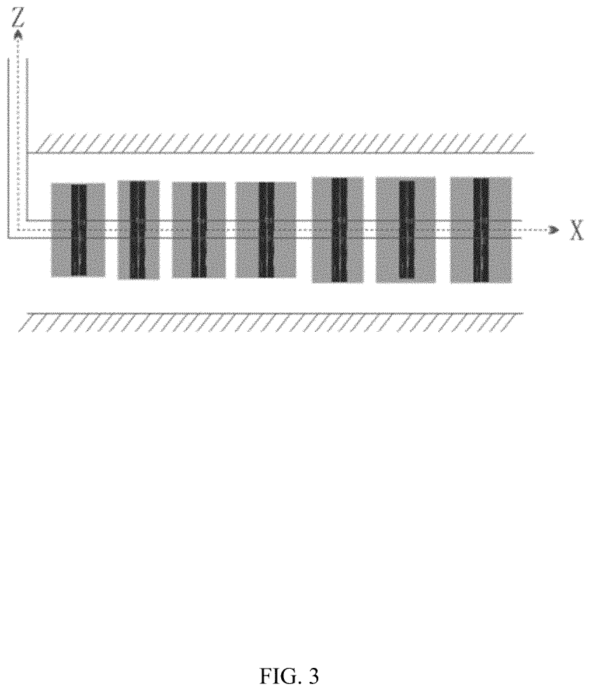

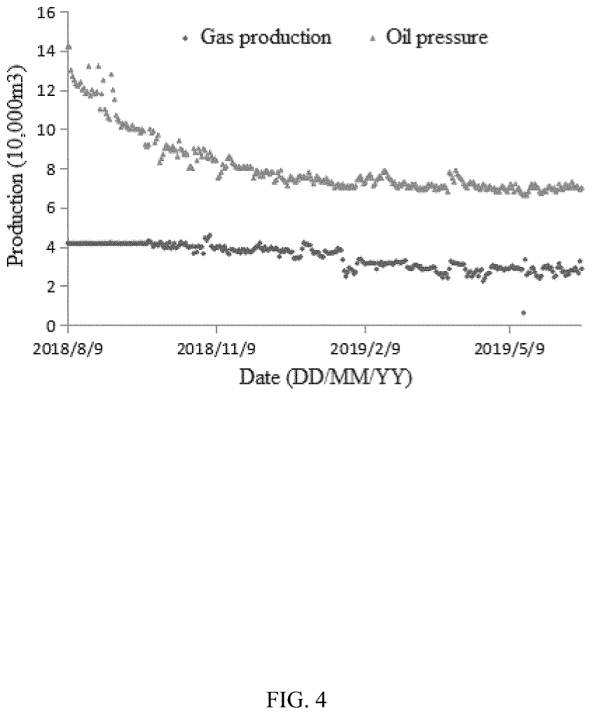

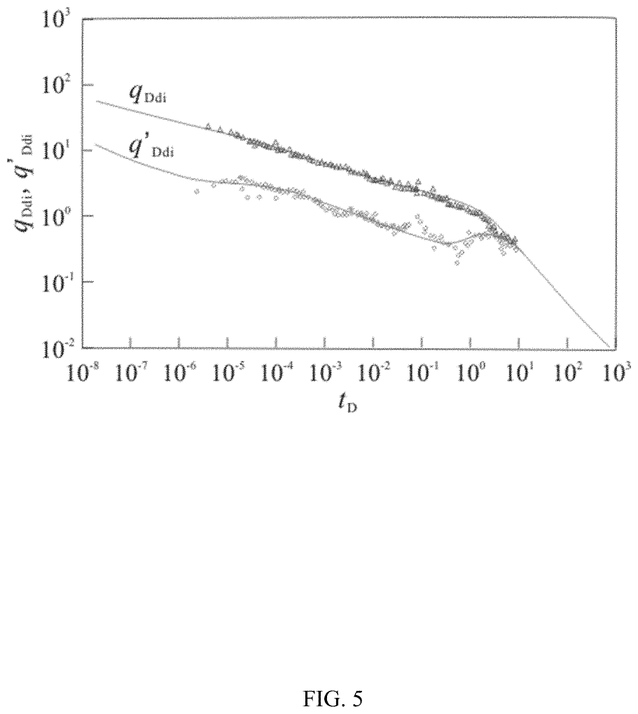

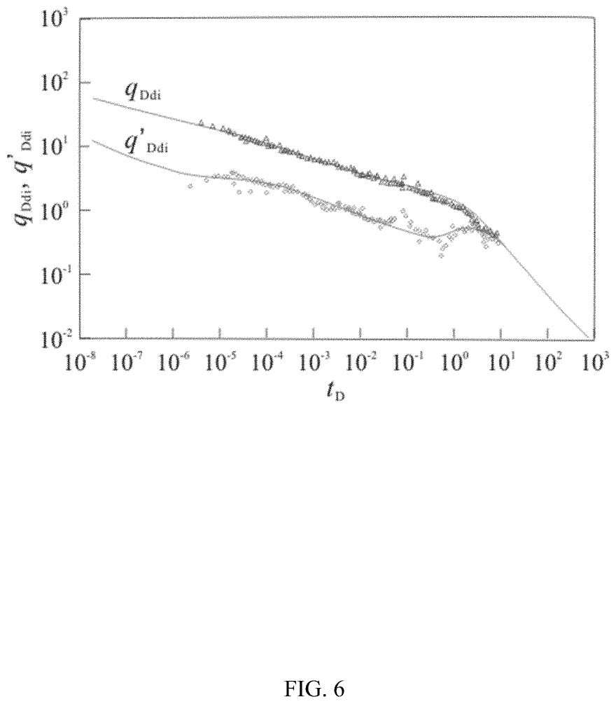

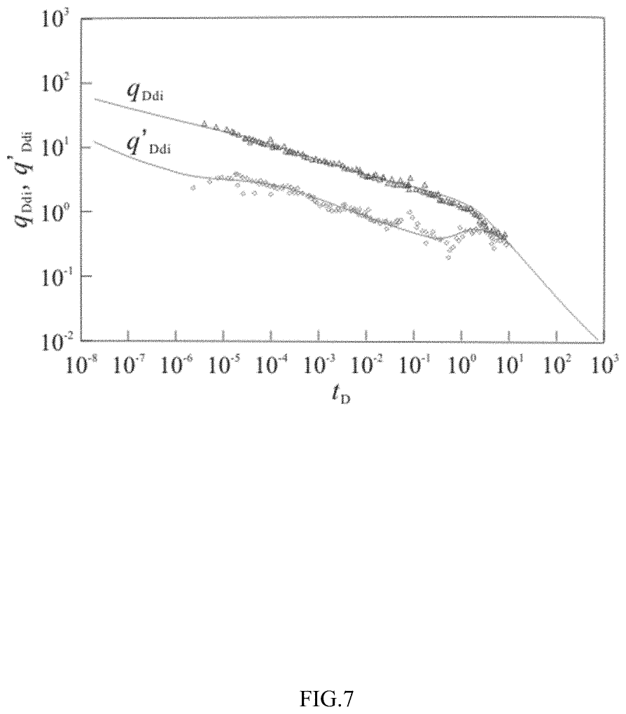

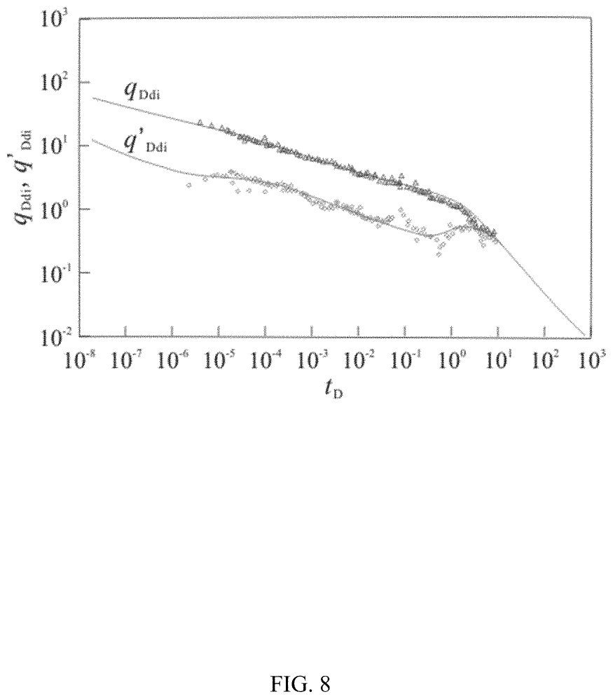

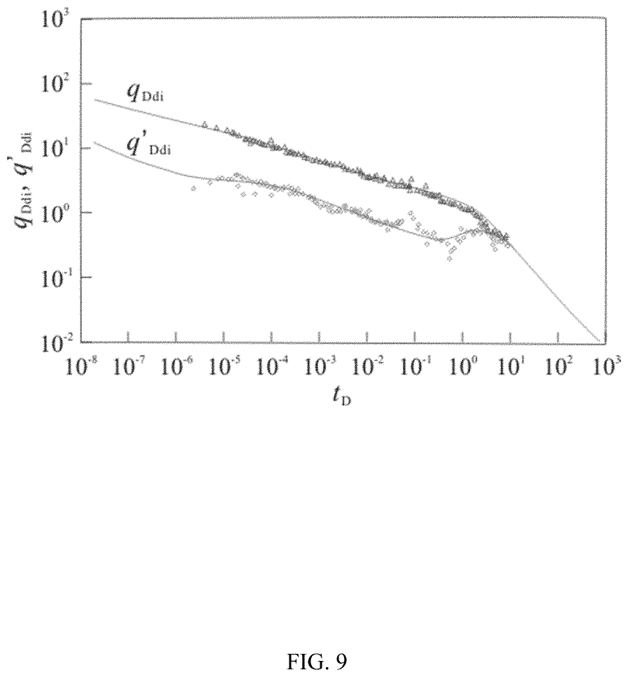

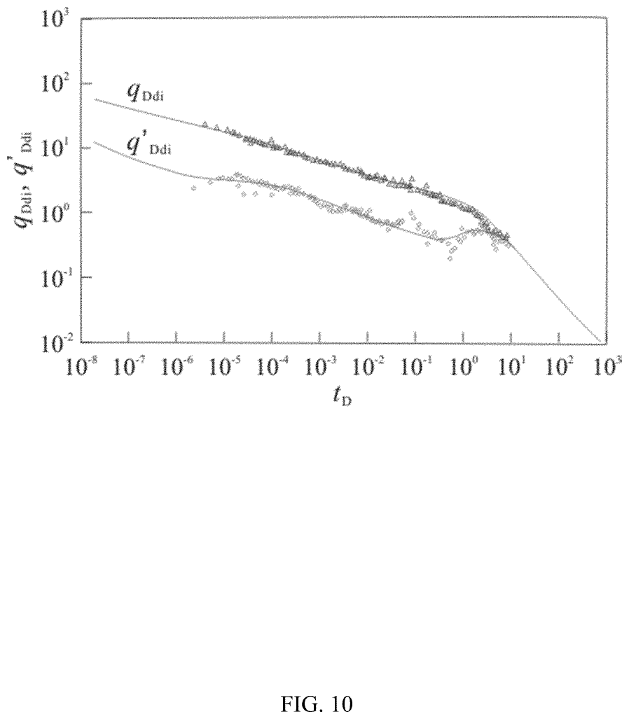

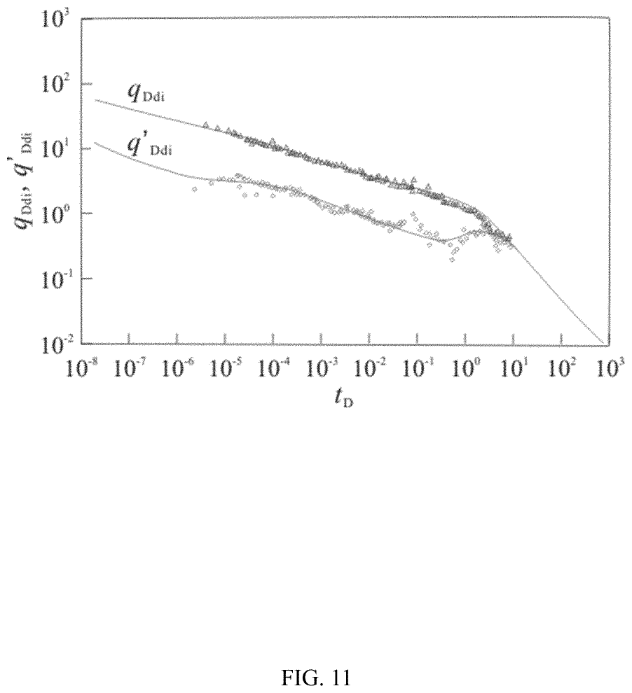

As shown in FIGS. 1-11, in the study case of multi-stage fractured horizontal well (Well H1) in a unconventional tight gas reservoir in the Ordos Basin, Well H1 has a total of 7 fracturing stimulation intervals, and was formally put into production on Aug. 9, 2018, the reservoir is drilled 2,767.77m deep, and the test instrument is set into the reservoir at 2,200m deep. A method for determining the characteristic parameters of stimulation intervals of multi-stage fractured horizontal well in unconventional oil and gas reservoir, comprising the following steps:

Step 1: Collect and sort out basic information and data of the multi-stage fractured horizontal well in unconventional oil and gas reservoir, as shown in Table 1;

TABLE 1
Logging Data of Well H1 and Basic Information of the Reservoir

| | | Compression | Volume | | Deviation | | |
|---|---|---|---|---|---|---|---|
| | Viscosity | coefficient | coefficient | | factor | Original gas | |
| Well No. | μ (mPa · s) | Cₜ (1/MPa) | Bg | | Z | saturation Sg | |
| H1 | 0.01797 | 0.0474 | 0.0056 | | 0.8926 | 0.7 | |
| Ordering of | Interval | Interval | Interval | Interval | Interval | Interval | Interval |
| Stimulation | 1 | 2 | 3 | 4 | 5 | 6 | 7 |
| Intervals | | | | | | | |
| Length of | 105 | 80 | 95 | 110 | 97 | 106 | 120 |
| stimulation | | | | | | | |
| intervals (m) | | | | | | | |
| Porosity of | 0.076 | 0.073 | 0.083 | 0.091 | 0.079 | 0.086 | 0.097 |
| stimulation | | | | | | | |
| intervals | | | | | | | |
| Gas | 0.65 | 0.72 | 0.75 | 0.69 | 0.63 | 0.59 | 0.52 |
| saturation | | | | | | | |

Step 2: Collect daily test pressure data of Well H1, screen and sort out the data according to the quality of the pressure data, and exclude the values with deviations greater than 20% from both left and right adjacent values.

Step 3: Collect daily test production data of Well H1, screen and sort out the data according to the quality of the production data, and exclude the values with deviations greater than 20% from both left and right adjacent values.

Step 4: According to the length, porosity, and gas saturation of the fracturing stimulation intervals at all stages recorded in Table 1, figure out the weight coefficient in production splitting of each fracturing stimulation interval with Formula (2), and figure out the production after splitting of each fracturing stimulation interval with Formula (3), as shown in Table 2:

TABLE 2
Weight Coefficients in Production Splitting and Production after Splitting
of Fracturing Stimulation Intervals at All Stages of Well H1

| | Ordering of Stimulation Intervals | | | | | | |
|---|---|---|---|---|---|---|---|
| | Interval 1 | Interval 2 | Interval 3 | Interval 4 | Interval 5 | Interval 6 | Interval 7 |
| Weight coefficient Wᵢ | 0.13 | 0.11 | 0.15 | 0.18 | 0.13 | 0.14 | 0.16 |
| Production after | 0.13q | 0.11q | 0.15q | 0.18q | 0.13q | 0.14q | 0.16q |
| splitting qᵢ (10,000 m³) | | | | | | | |

Step 5: Select TOPAZE, a popular advanced production decline analysis software for oil and gas wells, and input the logging data and basic parameters of the reservoir recorded in Table 1 in Step 1, the pressure data described in Step 2, and the production data and corresponding time described in Step 4, and then draw the double logarithmic curve of dimensionless production integral and dimensionless production integral derivative with time respectively.

Step 6: Select a production decline fitting model for multi-stage fractured horizontal wells in the software, conduct parameter adjustment and fitting for each fracturing stimulation interval according to the double logarithmic curve described in Step 5 and the ordinal number of each fracturing stimulation interval, and obtain the fracture characteristic parameters and reservoir characteristic parameters of each fracturing stimulation interval, as shown in Table 3.

TABLE 3
Production Decline Analysis and Fitting Interpretation Results of All Fracturing
Stimulation Intervals in Well H1

| | Ordering of Stimulation Intervals | | | | | | |
|---|---|---|---|---|---|---|---|
| | Interval | Interval | Interval | Interval | Interval | Interval | Interval |
| | 1 | 2 | 3 | 4 | 5 | 6 | 7 |
| Fracture half-length X_{f}; | 140 | 150 | 144 | 147 | 156 | 151 | 155 |
| (m) | | | | | | | |
| Fracture conductivity F_{C}, | 52 | 73 | 79 | 61 | 69 | 67 | 77 |
| (mD · m) | | | | | | | |
| Horizontal permeability | 0.345 | 0.372 | 0.425 | 0.396 | 0.327 | 0.336 | 0.363 |
| kₕ, (mD) | | | | | | | |
| Vertical permeability kᵥ, | 0.00458 | 0.00729 | 0.00967 | 0.00535 | 0.00673 | 0.00564 | 0.00652 |
| (mD) | | | | | | | |
| Skin coefficient S | −1.31 | −1.64 | −0.67 | −0.98 | −1.27 | −1.32 | −1.43 |

In the successful application in this well, it is proved that the method for obtaining reservoir characteristic parameters and fracture characteristic parameters of all stimulation intervals of multi-stage fractured horizontal well in unconventional oil and gas reservoir proposed by the present invention is highly feasible and practical, and worth applying widely.

The above are only the preferred embodiments of the present invention, and are not intended to limit the present invention in any form. Although the present invention has been disclosed as above with the preferred embodiments, it is not intended to limit the present invention. Those skilled in the art, within the scope of the technical solution of the present invention, can use the disclosed technical content to make a few changes or modify the equivalent embodiment with equivalent changes. Within the scope of the technical solution of the present invention, any simple modification, equivalent change and modification made to the above embodiments according to the technical essence of the present invention, are still regarded as part of the technical solution of the present invention.

We claim:

1. A method for determining the characteristic parameters of stimulation intervals of multi-stage fractured horizontal well in unconventional oil and gas reservoir, comprising the following steps:
Step 1: Collect and sort out basic information and data of the multi-stage fractured horizontal well in unconventional oil and gas reservoir;
Step 2: Collect daily test pressure data of the multi-stage fractured horizontal well in unconventional oil and gas reservoir, and screen and sort out the data according to the quality of the pressure data;
Step 3: Collect daily test production data of the multi-stage fractured horizontal well in unconventional oil and gas reservoir, and screen and sort out the data according to the quality of the production data;
Step 4: Split the production data sorted out in Step 3 to obtain the production data of fracturing stimulation intervals at all stages;
Step 5: Select popular advanced production decline analysis software for oil and gas wells, input the basic information and data of the well and reservoir described in Step 1, the pressure data described in Step 2, and the production data and corresponding time described in Step 4, and draw the double logarithmic curve of dimensionless production integral and dimensionless production integral derivative with time respectively;
Step 6: Fit and interpret the stimulation intervals at all stages according to the double logarithmic curves described in Step 5 to obtain the fracture characteristic parameters and reservoir characteristic parameters of fracturing stimulation intervals at all stages.

2. The method for determining the characteristic parameters of stimulation intervals of multi-stage fractured horizontal well in unconventional oil and gas reservoir according to claim 1, wherein the basic information and data of the well and the reservoir described in Step 1 include fluid viscosity, compression coefficient, volume coefficient, deviation factor, original oil saturation or original gas saturation, length of stimulation interval, porosity of stimulation interval, and oil saturation or gas saturation of stimulation interval.

3. The method for determining the characteristic parameters of stimulation intervals of multi-stage fractured horizontal well in unconventional oil and gas reservoir according to claim 1, wherein values with deviations greater than 20% from both left and right adjacent values are excluded when the pressure data is screened and sorted out in Step 2.

4. The method for determining the characteristic parameters of stimulation intervals of multi-stage fractured horizontal well in unconventional oil and gas reservoir according to claim 1, wherein values with deviations greater than 20% from both left and right adjacent values are excluded when the production data is screened and sorted out in Step 3.

5. The method for determining the characteristic parameters of stimulation intervals of multi-stage fractured horizontal well in unconventional oil and gas reservoir according to claim 1, wherein the method used in Step 4 to split the production data sorted out in Step 3 to obtain the production data of fracturing stimulation intervals at all stages is as follows:
Step 41: According to the logging data collected in Step 1, record the length, porosity, oil saturation, or gas saturation of each fracturing stimulation interval;
Step 42: Determine the weight coefficient Wᵢ of each fracturing stimulation interval in the production splitting, specifically as follows:
$$\begin{matrix}{W}_{o i} = \frac{{L}_{i} {φ}_{i} {S}_{oi}}{{\sum }_{i = 1}^{N} ( {L}_{i} {φ}_{i} {S}_{oi} )} , ( i = 1 , 2 , … N ) & ( 1 ) \\ {W}_{g i} = \frac{{L}_{i} {φ}_{i} {S}_{gi}}{{\sum }_{i = 1}^{N} ( {L}_{i} {φ}_{i} {S}_{gi} )} , ( i = 1 , 2 , … N ) & ( 2 )\end{matrix}$$
Where,
Wₒᵢ refers to the weight coefficient of Fracturing Stimulation Interval i of the oil reservoir in the production splitting, which is dimensionless;
W_{gi} refers to the weight coefficient of Fracturing Stimulation Interval i of the gas reservoir in the production splitting, which is dimensionless;
Lᵢ refers to the length of Fracturing Stimulation Interval i, in m;
φᵢ refers to the porosity of Fracturing Stimulation Interval i, which is dimensionless;
Sₒᵢ refers to the oil saturation of Fracturing Stimulation Interval i, which is dimensionless;
S_{gi} refers to the gas saturation of Fracturing Stimulation Interval i, which is dimensionless;
Step 43: Calculate the production after splitting of each fracturing stimulation interval according to the weight coefficient Wᵢ of each fracturing stimulation interval determined in Step 42, specifically as follows:
qᵢ=Wᵢq, (i=1,2, . . . N) (3)
Where,
Lᵢ refers to the production of Fracturing Stimulation Interval i, in 10,000 m³;
Wᵢ refers to the weight coefficient of Fracturing Stimulation Interval i in the production splitting, which is dimensionless;
q refers to the daily production of the horizontal well, in 10,000 m³.

6. The method for determining the characteristic parameters of stimulation intervals of multi-stage fractured horizontal well in unconventional oil and gas reservoir according to claim 1, wherein in the process of fitting and interpretation in Step 6, the fitting and interpretation are conducted for each fracturing stimulation interval according to the ordinal numbers of fracturing stimulation intervals.

7. The method for determining the characteristic parameters of stimulation intervals of multi-stage fractured horizontal well in unconventional oil and gas reservoir according to claim 1, wherein in the process of fitting and interpretation in Step 6, a production decline fitting model for multi-stage fractured horizontal wells is selected to conduct parameter adjustment and fitting and obtain the fracture characteristic parameters and reservoir characteristic parameters of each fracturing stimulation interval.

8. The method for determining the characteristic parameters of stimulation intervals of multi-stage fractured horizontal well in unconventional oil and gas reservoir according to claim 1, wherein the fracture characteristic parameters include the conductivity and half-length of fracture, and the reservoir characteristic parameters include the horizontal permeability, vertical permeability and skin of the reservoir.
